(19) United States
(12) Patent Application Publication
(10) Pub. No.: US 2015/0122178 A1
(43) Pub. Date: May 7, 2015

(54) REACTION CHAMBER FOR DEPOSITION OF A SEMICONDUTOR LAYER ON THE PLURALITY SUBSTRATES IN BATCHES

(71) Applicant: Gyorgy Strausz, Budaors (HU)

(72) Inventors: Zsolt Vadadi, Budapest (HU); Tamas Strausz, Budaors (HU); Peter Nemeth, Szombathely (HU)

(73) Assignee: ECOSOLIFER AG, Sarnen (CH)

(21) Appl. No.: 14/238,842

(22) PCT Filed: Aug. 14, 2012
(86) PCT No.: PCT/HU2012/000074

§ 371 Date: Nov. 12, 2014

(30) Foreign Application Priority Data
Aug. 15, 2011 (HU) P1100437

(51) Int. Cl. C23C 16/455; C23C 16/46; C23C 16/458

(52) U.S. Cl. CPC C23C 16/45504; C23C 16/458; C23C 16/46
USPC 118/723 R

(57) ABSTRACT

A reaction chamber for deposition of a semiconductor layer or layer structure on the plurality of substrate surfaces in substrate batches wherein the chamber comprises a body with an inner volume and a closing bottom lid, in the inner volume rectangular substrates are aranged spaced apart from each other and electrodes suitable for providing high-frequency electromagnetic field are disposed between the substrates; and the space presenting between the surfaces to be deposited provide flow channels making available the laminar flow of reaction gases between two opposite sides of the chamber, and the chamber is characterized in that the closing bottom lid can be opened in the vertical up-and-down direction, and the lid comprises supporting frames for holding the substrates from the bottom and along the side edges, and the supporting frames are provided with adequate recesses to enable them to perform this supporting function.

The present invention refers to a reaction chamber for deposition of a semiconductor layer or layer structure on a surface of a plurality of substrates in substrate batches with improved loading/unloading system.

Such reaction chambers comprise a body with an inner volume and an upper lid and closing bottom lid, in the inner volume rectangular plate-like substrates are arranged in a spaced apart relationship with each other and electrodes suitable for providing high-frequency electromagnetic field in order to deposit a thin material layer are disposed between the substrates; each electrode is disposed in a spaced-apart relationship adjacent to the surface of the substrate not to be deposited; and each space extending between the surfaces to be deposited forms a flow channel making available the laminar flow of reaction gases between two opposite sides of the chamber; the opposite electrodes are connected to a high-frequency generator and the closed inner volume of the chamber is provided with a heating element.

The most common types of so the called batch-processing equipments—which are applicable to simultaneously deposit various layers onto a plurality of large substrates—are known from documents CN 101626049 and P0700164.

Document CN 101626049 discloses a method for manufacturing a film solar cell, which comprises the steps of mounting substrates on respective surfaces of a plurality electrode plates in a reaction chamber, the electrodes supporting the substrates are introduced one by one into a CVD thin layer deposition chamber, then the electrodes supporting the substrates are each connected to a respective RF generator supplying RF power, subsequently a reaction gas of predetermined composition is introduced into the chamber, and RF plasma discharge is formed in the chamber in order to produce various thin layers.

Hungarian patent application No. P0700164 discloses an apparatus which has an inner reaction volume, in the reaction volume a plurality of parallel, planar, spaced apart electrode pairs are arranged, and the planar electrodes on their opposite surfaces support a plurality of substrates envisaged to be subject of layer deposition. During normal operation of this apparatus the substrates can be loaded only in the unloaded state of the electrodes from the chamber, and substrates must be placed onto the electrode surfaces one by one outside the reaction chamber, and the electrodes and substrates are loaded together again into the reaction chamber. The loading of electrodes is done individually or in electrode batches.

In the solutions proposed in the prior art during loading and unloading of the substrates the electrodes must also be removed. In every loading/unloading step the electrodes are connected to the plugs in the inner volume of the chamber manually. Such one by one loading increases the idle periods of the apparatus and the frequent connection and disconnection of electrodes and plugs in every loading/unloading cycle is a source of failure. These operations are not susceptible to automation.

Object of the present invention is to provide an improved substrate loading system for which the idle time is lower compared to prior art methods and which loading system can be automated.

Further object of the present invention is to provide an improved substrate loading system in which loading and unloading is performed along one single spatial direction of the chamber, and other devices corresponding to other functions of the chamber (such as gas distribution) are arranged along different spatial directions, thus different functions of the chamber and devices performing these different functions are geometrically separated from each other.

According to the invention the above objects are achieved with an improved loading system for a reaction chamber for deposition of a semiconductor layer or layer structure on at least one surface of a plurality of substrates, the chamber comprising a body with an inner volume and an upper lid and a closing bottom lid, in the inner volume preferably rectangular, plate-like substrates are arranged in a spaced apart relationship with each other; and electrodes suitable for providing high-frequency electromagnetic field in order to deposit a thin material layer are disposed between the substrates; each electrode is disposed in a spaced-apart relationship adjacent to the surface of a substrate not to be deposited; each space extending between the substrate surfaces to be deposited forms a flow channel making available the laminar flow of reaction gases between two opposite sides of the chamber, and the opposite electrodes are connected to a high-frequency generator and the closed inner volume of the chamber is provided with a heating element, and the main characteristic of the loading system is that the closing bottom lid of the reaction chamber can be opened in the vertical up/down direction, and the lid comprises supporting frames for surrounding and holding the substrates from the bottom and along their side edges, the supporting frames being arranged at a distance to each other, and the supporting frames are provided with adequate recesses for the substrates and the electrodes, said volumes are defined by the distance of recesses of the frames and width of the gas flow channels is defined by the distance between adjacent supporting frames, and the bottom lid together with the supporting frames and the substrates inserted into said recesses form a mechanically integrated body, which body in the form of a loading container can be loaded into, fixed in and unloaded from the inner volume of the chamber, and the electrodes are suspended from the upper lid, and during loading of the loading container their side and bottom edges are guided and locked by the recesses of the supporting frame corresponding to the electrodes.

In the following description an advantageous embodiment of the invention will be described in detail with reference to the attached drawing, wherein in

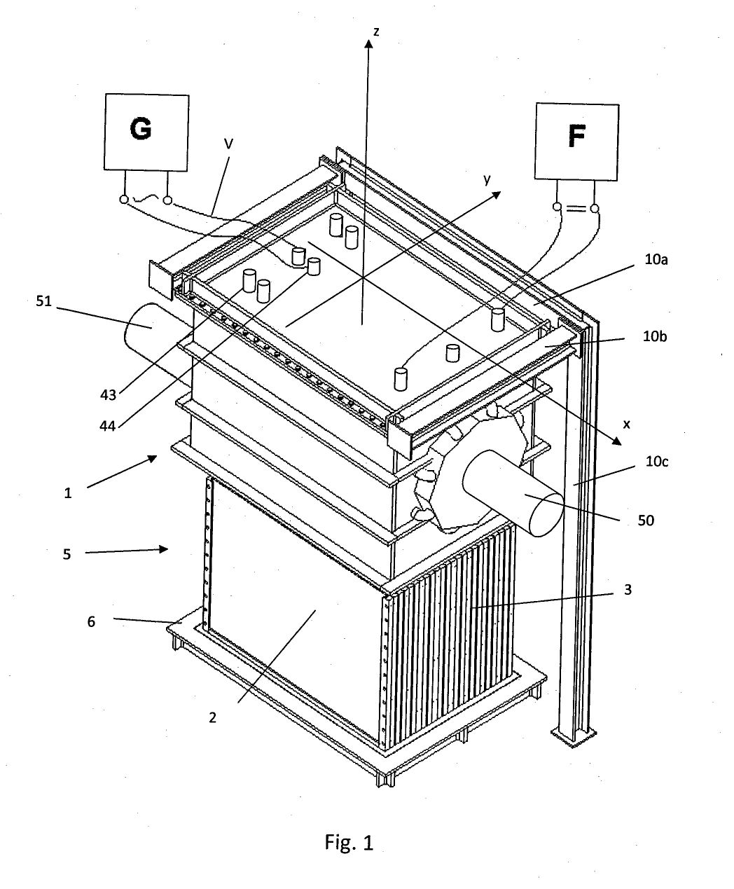

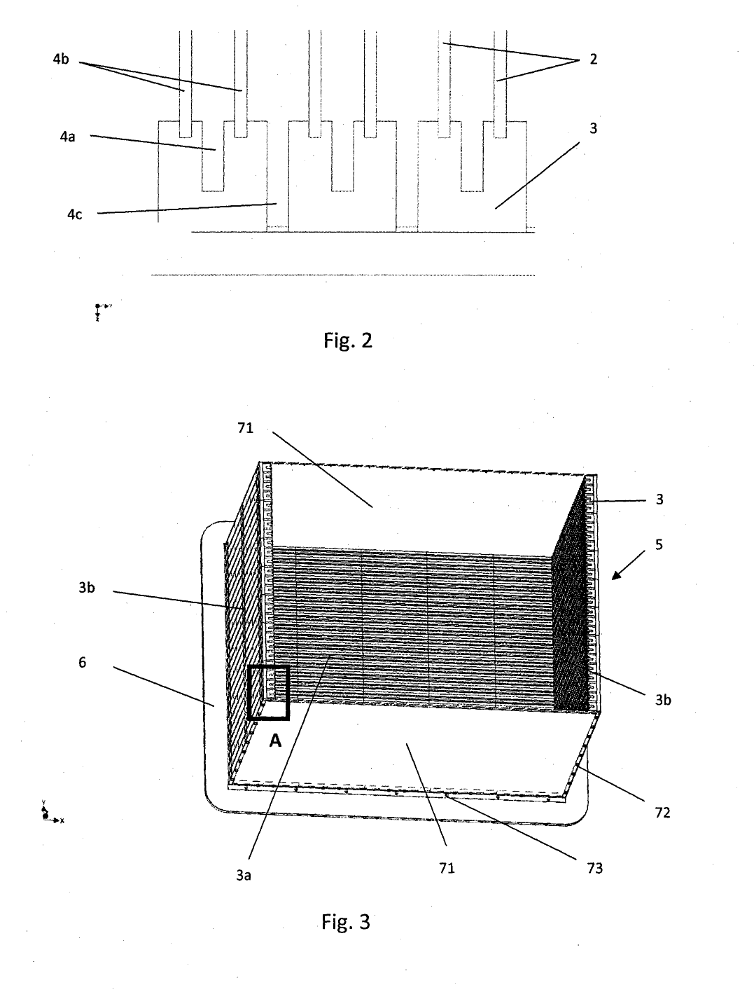

FIG. 1 a reaction chamber supported by a structure of metal profiles is shown in perspective view, FIG. 2 is a top view of the supporting frames which are placed adjacent to each other and in which the substrates will be inserted, in

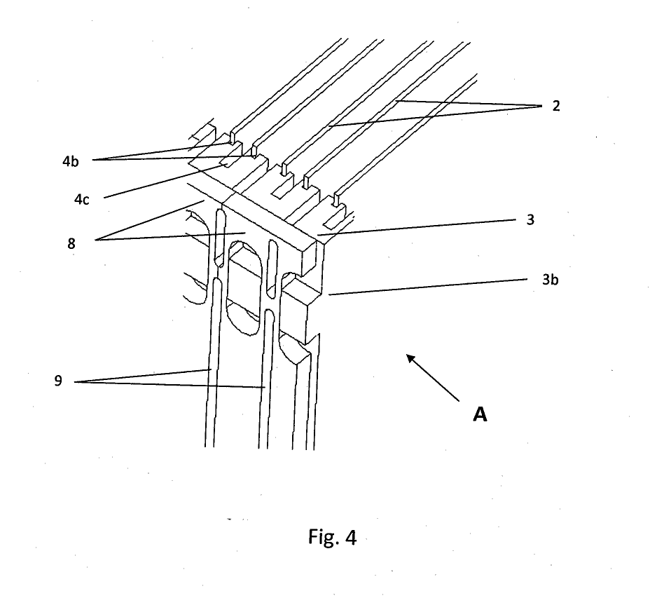

FIG. 3 a loading container containing a plurality of adjacent supporting frames is shown in perspective top view, in

FIG. 4 detail “A” of FIG. 3 can be seen in an enlarged view, wherein three adjacent supporting frame is shown in perspective view, and

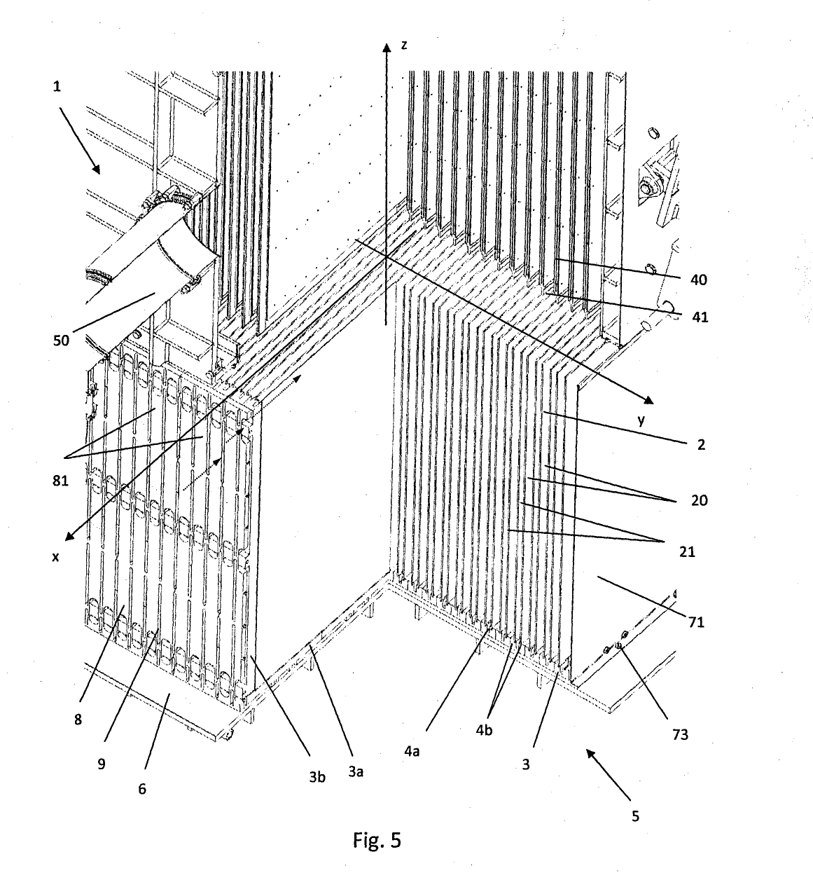

FIG. 5 is a perspective, partially cut-out sectional view of the reaction chamber, wherein the chamber is rotated by −90° with respect to the view of FIG. 1.

The reaction chamber 1 in FIG. 1 has a framework made of 10a, 10b, 10c consoles. The 10a, 10b, 10c consoles are perpendicular to each other and are arranged along x, y and z directions, respectively. Dimensions and materials of the 10a, 10b, 10c consoles are selected so as to have sufficiently large load bearing capacity for holding the reaction chamber 1 which is very heavy in its loaded state. In the drawing it is not shown, but the walls provide an air tight sealing of the reaction chamber 1 and during operation in the inside of the reaction chamber 1 a background pressure lower than the atmospheric pressure is present, which is necessary for the reaction. The inner volume of the reaction chamber 1 comprises a structure of parallel, spaced apart plates. Said inner structure is partially made up by substrates 2, here substantially rectangular glass plates—depicted in the enlarged partial view of FIG. 2—and on one surface of the glass plates a semiconductor thin layer or thin layer structure is to be deposited in the reaction chamber 1, for example by a CVD process and finally, on said plates photovoltaic devices are formed. The thin layer structure may comprise layers not made of semiconductor materials; such layers are built in a separate deposition step in the same or in a different reaction chamber 1. Such deposition step may comprise e.g. the formation of a slightly conducting layer on top of the active surface of the glass substrates 2. In FIG. 1 it is schematically shown that the substrates 2 are surrounded and supported along their side edges and along their bottom by supporting frames 3. These frames form an interconnected supporting structure, this structure being attached to the bottom closing lid 6 of the reaction chamber 1. This whole mechanical structure in the form of a loading container 5 can be loaded in a properly guided manner into the reaction chamber 1 from the bottom, upwards along the z direction and when the layers are deposited the loading container can be unloaded. In FIG. 1 the whole structure is shown at the beginning of the loading step.

In the same figure there is shown the upper lid of the reaction chamber 1 with connectors V to which a heater F and a generator G is connected through wiring. The heater F is connected by means of connecting elements which also have a function of 43 threaded rods. A further connecting element 44 protruding from the upper lid of the reaction chamber 1 is used for the connection of the radio frequency generator G. On the upper lid of the reaction chamber 1 a number of such threaded rods 43 and connecting elements 44 are arranged in a manner to be described later in detail. In this diagrammatic view only three of them are shown in order to schematically represent the connection of the heater F and the generator G.

On the two opposite sidewalls of the reaction chamber 1 perpendicular to the y direction an inlet channel 50 for introducing the reaction gases and an outlet channel 51 for removing the reaction byproducts are arranged. Between the inlet channel 50 and the outlet channel 51 the direction of gas flow is parallel to the plane of substrates 2.

FIG. 2 is a top view of an enlarged section of the supporting frames 3 in which the substrates 2 are inserted. In the inventive batch-processing equipment, which is capable to simultaneously handle a plurality of large 2 substrates, a number of supporting frames 3 are placed adjacent to each other—in FIG. 2 three of them is shown. Each supporting frame 3 comprises three recesses: two recesses 4b of identical shape and thickness, and a third recess 4a formed between said two recesses 4b and being deeper and having larger width than said two recesses 4b. Recesses 4b have a dimension so that substrates 2/e.g. glass plates used as substrates/can snugly fit into them. Thickness of the substrates 2 is between about 0.5 mm and 5 mm, preferably 2 mm, thus the width of said two recesses 4b is also in this range. The actual width of recess 4b must be determined in advance, e.g. by etching, according to the actual size of substrates 2 to be used in the apparatus. The supporting frames 3 are made of an electrically insulating and mechanically rigid material, which also have sufficient resistance against compositions participating in the reaction to be carried out in the inner volume of the reaction chamber 1 and can also withstand high pressure and high temperature existing in the chamber. The supporting frames 3 are placed adjacent to each other in a periodic structure. For example in FIG. 2 going from left to right first comes a recess 4b which belongs to a first supporting frame 3, then recess 4a and again recess 4b belonging to the same frame 3 is seen, then we see a very narrow gap 4c dividing the first supporting frame 3 from the next adjacent supporting frame 3, then recess 4b, recess 4a and again recess 4b of the adjacent supporting frame 3 is seen etc.

In FIG. 3 the loading container 5 to be introduced into the reaction chamber 1 is shown in elevational perspective view from above and for the sake of better visibility some details are hidden. For example the substrates 2 which are supported in the recesses 4b are not seen. Each supporting frame 3 consists of two lateral frame parts 3b and a bottom frame part 3a which together are joined to a single, rigid mechanical structure. The supporting frame 3 is open from above, thus it supports the substrates 2 only on the bottom and from the sides. This is particularly important, since the substrates 2 are inserted into the recesses 4b of the supporting frame 3 from the top which is kept open. In the loading container 5 built up by a plurality of supporting frames 3 the following periodic structure is seen—using reference signs of FIG. 2: a recess 4b then a recess 4a and again recess 4b of the same supporting frame 3, then a small gap 4c between two adjacent supporting frames 3 and in the loading container 5 this period is repeated in a finite number. The number of supporting frames 3 is chosen on the basis of practical aspects, their number is preferably 25 to 50. Here the number of substrates 2 to be loaded is twice the number of frames. Each supporting frame 3 in the loading container 5 has the same dimensions. The supporting frames 3 and their recesses can firmly support the large glass plate substrates 2 during loading and unloading operations and the reaction. Lateral frame parts 3b of each supporting frame 3 are slightly longer than the height of the substrates 2; whereas the bottom frame parts 3a of the supporting frames 3 are slightly longer than the width of substrates 2. Size of the substrates 2 corresponds to the size foreseen for the devices to be fabricated and can be set to different values. The most preferred range is between 50 cm×75 cm and 150 cm×200 cm; a very frequently used dimension is 100 cm×150 cm.

The supporting frames 3 which comprise more frame parts are made of an electrically insulating material. Such materials can be chosen among plastics or ceramics, e.g. alumina or Teflon, but for this purpose other electrically insulating materials with high mechanical hardness can also be used i.e. glass, minerals, composite materials etc. It is not excluded to make the supporting frames 3 of metal, however, in this case the metal surface must be covered by an insulation layer.

The bottom of the loading container 5 is fastened to the bottom closing lid 6 which is disposed below the bottom frame parts 3a and is attached to the supporting frames 3 and has a broad rim portion. In order to make the structure more rigid the two outermost supporting frames 3 limiting the loading container 5 in the lateral direction are connected to fastening plates 71 and on the rear side or in the middle of the vertically oriented lateral frame parts 3b apertures are provided through which threaded bolts 72 are guided in the transversal direction, the ends of the bolts are fastened by means of nuts, and these bolts keep all lateral frame parts 3b together. Similarly, on the bottom the bottom frame parts 3a are kept together by threaded bolts 73 and corresponding nuts. The whole structure is held together on the bottom by the bottom closing lid 6.

In FIG. 4 detail “A” of FIG. 3 is shown in enlarged perspective view, wherein the substrates 2 which were invisible in FIG. 3 are also depicted. Three supporting frames 3 are arranged next to each other, and a possible connection of the supporting frames 3 is also exemplified. To each lateral frame part 3b of the supporting frames 3 ribs 8 are attached by means of releasable connecting means, e.g. bolts. Each rib 8 is responsible for holding together three supporting frames 3. The ribs 8 are provided with openings, e.g. by grooves 9 which are positioned so as to overlap with the gaps 4c between the adjacent supporting frames 3 when the ribs 8 are mounted onto the frames. Thanks to this arrangement during the CVD process the gases entering the reaction chamber 1 must flow through the grooves 9 of the ribs 8 and subsequently through the gaps 4c between adjacent supporting frames 3 and by flowing further towards the inside of the loading container the reaction gases enter into the volumes 20 extending along the substrate 2 surfaces to be deposited. Thus, these volumes 20 are used as reaction volumes, which serve for plasma generation and serve as a place of chemical reactions.

In FIG. 5 the reaction chamber 1 is shown in a partially cut-out, perspective view, with the loading container 5 being in an intermediate phase of loading. The cut-out is made such that one quarter of the chamber is removed at a one corner of the reaction chamber 1 and the important elements inside are also visible. The reaction chamber 1 is rotated by −90° degree with respect to the view of FIG. 3, which can be observed from the different orientation of the substrates 2. In order to provide better visibility of the change of orientation x, y and z directions are also shown. The x, y, z directions form here as well a right-handed coordinate system, however the x and y axes point to other directions, rotated by −90° degree.

From the upper part of the reaction chamber 1 planar, rectangular, spaced apart, equidistant and parallel electrodes 40 are suspended towards the bottom and during the upwards movement of the frames each electrode along its width reaches into recesses 4a of the supporting frames 3 and the recesses support and guide the electrodes. In this manner an interpositioned, comb-shaped plate structure is formed, in which two substrates 2 always enclose an electrode 40, and on the side of the substrates 2 opposite to the electrodes 40 a volume suitable for gas flow is formed. Due to this advantageous arrangement during introduction into the reaction chamber 1 the substrates 2 line up in a comb-shaped manner between the electrodes 40 which are fixed in their positions in the chamber 1. Between the substrates 2 volume 20 and volume 21 are alternating. The volumes 20 are reaction volumes for reaction gases. Into volumes 21 the electrodes 40 are inserted. Loading is completed when the substrates 2 are all the way slid into the reaction chamber 1 with the electrodes 40 interpositioned between them. In this position the flattened part 41 (rims) of each electrode 40 fits into recess 4a of the respective supporting frame 3 and is firmly supported and guided therein. In each recess 4a the respective electrode 40 is inserted with a small play such that sufficiently large space is left for deformations due to thermal dilatation. Even further, electrode 40 is inserted with a small play into volume 21 between two substrates 2 such that sufficiently large space is left between the substrate 2 and the electrode 40 for deformation due to thermal dilatation. As it has been shown earlier recess 4a is deeper than the two recesses 4b encompassing it. Consequently, in a completely loaded position the electrodes 40 slightly reach over the surfaces of the substrates 2. In this manner we achieve that in the region of the substrate 2 surfaces inhomogeneous plasma conditions and related fluctuations and transient processes of the deposition conditions are suppressed and the quality and thickness of the deposited layer is homogeneous.

Thus, in the fully loaded position the electrodes 40 and the substrates 2 which are completely slid between them form a sandwich structure in which e.g. the following come periodically in a consecutive order: a substrate 2 placed into a recess 4b corresponding to a first supporting frame 3, an electrode 40 placed into recess 4a, again a substrate 2 placed into recess 4b, then the volume 20 between substrates 2 of two adjacent supporting frames 3 (which volume is eventually a broadened extension of the gap 4c between two adjacent supporting frames 3 and extends further between the substrates 2), then a subsequent substrate 2 inserted into recess 4b corresponding to a supporting frame 3 next to the first one, an electrode 40 inserted into recess 4a and again a substrate 2 inserted into recess 4b etc. In the loading container 5 introduced into the reaction chamber 1 this periodic structure is repeated in finite number.

It is observable mainly from FIG. 1 that electrode 40 comprises two threaded bolts 43 protruding from the upper part of the electrode 40. Said threaded bolts 43 fit into holes provided in the upper lid of the reaction chamber 1 and said threaded bolts 43 are fastened to the lid of the reaction chamber 1 by releasable connecting elements, e.g. by screws. The threaded bolts 43 serve—beyond fastening—as electric connectors for the electric power supply of the heater F cable to be described in detail later. At the upper edge of the electrode 40 a further connecting element 44 is disposed for connecting the RF generator G. The suspension is realized by means of releasable connection, however, during normal operation conditions e.g. between two CVD cycles these connections do not need to be disconnected. This means that the heating F cables and the connections of the RF generator G do not need to be disconnected, which makes the implementation of the CVD process easier, more reliable and as a result, productivity is improved.

Also in FIG. 5 it is shown that the loading container 5 along its bottom side is fastened to the bottom closing lid 6. The outermost supporting frames 3 limiting the loading container 5 in the lateral direction are connected to fastening plates 71 and releasable fastening elements, e.g. screws which firmly hold in place the fastening plate 71 with respect to the closing lid 6.

Ribs 8 are attached to the lateral frame parts 3b of the supporting frames 3. One single rib 8 accounts for connecting three adjacent supporting frames 3. In this figure the boarder lines 81 between the ribs are visible. Further, between the grooves 9 of the ribs 8, in the gaps 4c between the supporting frames 3 and in the volumes 20 between two substrates 2 along the path marked by dashed arrows a free gas flow channel is formed. By this arrangement during the CVD process gases can flow through the reaction chamber 1.

A main feature of the reaction chamber 1 is that the electrodes 40 are suspended from the inner side of the upper part of the reaction chamber 1—using directions of FIG. 5. The suspension is effected by releasable connection, however during normal operation conditions, e.g. between two

CVD reaction cycles, these connections need not to be disconnected. Disconnection of the electrodes 40 might be necessary for example in case of maintenance works. This means that the heating F cables connected to the electrodes 40 and the connections of the radio frequency generator G need not to be disconnected, which makes the implementation of the CVD process easier, more reliable and as a result productivity is improved.

A further important feature of the present invention is that the plurality of electrodes 40 is aligned parallel to the plurality of substrates 2 and perpendicular to the plane of the bottom closing lid 6, and during loading the electrodes 40 and substrates 2 line up with each other in a comb-shaped manner, and there is no need for manually mounting the substrates 2 one by one onto the surface of electrodes 40. According to the invention the connections of the generator G and the heater F, the gas distribution system for providing a process gas flow—gas flow channel is denoted by reference number 50 in FIG. 5—and the bottom closing lid 6 are each arranged according to different x, y, z orthogonal directions of the reaction chamber 1 on its six faces. Thus, different functions of the reaction chamber 1 are separated according to different spatial directions.

Using x, y and z directions according to FIG. 5 the most preferred embodiment is where the loading container 5 and the closing bottom 6 attached thereto are moved along the z axis. Further, the connections coupling the electrodes 40 to the heater F and the generator G are also realized along the z axis, e.g. on the upper side of the chamber opposite to the bottom closing lid 6. In this embodiment the gas flow channel is formed in the y direction and the introduction of reaction gases and draining of reaction byproducts is realized in the y direction on two opposite faces of the chamber. In this manner it is advantageously achieved that the loading/unloading direction of the chamber 1 is orthogonal to the gas flow direction. By implementing different functions in different directions various elements of the reaction chamber 1 and processes carried out by said various elements are well separated from each other. It is also conceivable to have an alternative geometrical arrangement e.g. in which the loading container 5 and the closing bottom 6 attached thereto are moved along the vertical z axis, the connections coupling the electrodes 40 to the heater F and the generator G are realized on a side along the x axis and the gas flow channel is formed in the y direction so that the introduction of reaction gases and draining of reaction byproducts is realized in the y direction on two opposite faces of the chamber.

1. Reaction chamber (1) for deposition of a semiconductor layer or layer structure on at least one surface of a plurality of substrates (2) comprising a body with an inner volume and an upper lid and a closing bottom lid (6), in the inner volume rectangular, plate-like substrates (2) are arranged in a spaced apart relationship with each other and electrodes (40) suitable for providing high-frequency electromagnetic field in order to deposit a thin material layer are disposed between the substrates (2); each electrode (40) is disposed in a spaced-apart relationship adjacent to the surface of a substrate (2) not to be deposited and the space extending between the substrate (2) surfaces to be deposited forms a flow channel making available the laminar flow of reaction gases between two opposite sides of the chamber (1), the opposite electrodes (40) are connected to a high-frequency generator (G) and the closed inner volume of the chamber (1) is provided with a heater (F), characterized in that
the closing bottom lid (6) of the reaction chamber (1) can be opened in the vertical up/down direction, and
the lid comprises supporting frames (3) for surrounding and holding the substrates (2) from the bottom and along their side edges, said supporting frames (3) are arranged at a distance to each other, and the supporting frames (3) are provided with adequate recesses (4a, 4b) for the substrates (2) and for the electrodes (40), and
said volumes are defined by the distance of recesses (4a, 4b) of the frames (3), and width of the gas flow channels is defined by the distance between adjacent supporting frames (3), and
the bottom lid (6) together with the supporting frames (3) and the substrates (2) inserted into said recesses (4b) form a mechanically integrated body, which body in the form of a loading container (5) can be loaded into, fixed in and unloaded from the inner volume of the chamber (1), and
the electrodes (40) are suspended from the upper lid, and during loading of the loading container (5) their side and bottom edges are guided and locked by the recesses (4a) of the supporting frame (3) corresponding to the electrodes (40).

2. Reaction chamber (1) according to claim 1, characterized in that the supporting frames (3) are made of an electrically insulating, heat resistant material, and their outer parts are mechanically connected to each-other so that they form a solid, integrated body and into the recessed (4b) inner volume of the supporting frames the substrates (2) can be loaded from above.

3. Reaction chamber (1) according to claim 1, characterized in that the recesses (4b) of the supporting frames (3) suitable for receiving the substrates (2) have smaller depth than the recesses (4a) suitable for receiving the electrodes (40).

4. Reaction chamber (1) according to claim 1, characterized in that the structure connecting the supporting frames (3) is provided on the opposite sides of the chamber with openings (9) suitable transmit gases, the openings being aligned with said gas flow channel.

5. Reaction chamber (1) according to claim 1, characterized in that the chamber has a rectangular shape, wherein the gas flow channels open to two opposite side walls which are each perpendicular to the upper lid and the closing bottom lid (6), respectively, and on the side walls a gas inlet channel (50) and a gas outlet channel (51) is formed.

6. Reaction chamber (1) according to claim 1, characterized in that the supporting frames (3) which hold the substrates (2) from the bottom and along their side edges are assembled from three interconnected supporting frame (3) parts.

7. Reaction chamber (1) according to claim 1, characterized in that the electrical connection between the electrodes (40) and the high-frequency generator (G) can be maintained during loading and unloading of the loading container (5).

8. Reaction chamber (1) according to claim 1, characterized in that the electrode (40) is built up by two spaced apart plates which define a closed inner volume in which heating elements are disposed, and the electrodes (40) also fulfill the function of a heating element.
